(19) United States
(12) Patent Application Publication
(10) Pub. No.: US 2009/0108471 A1
(43) Pub. Date: Apr. 30, 2009

(54) Wiring board of semiconductor device, semiconductor device, electronic apparatus, mother board, method of manufacturing wiring board of semiconductor device, method of manufacturing mother board and method of manufacturing electronic apparatus

(75) Inventor: Seiya Fujii, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/289,260

(22) Filed: Oct. 23, 2008

(30) Foreign Application Priority Data
Oct. 31, 2007 (JP) 2007-284164

(51) Int. Cl. H01L 21/44; H05K 1/03; H01L 21/00; H01L 23/52

(52) U.S. Cl. 257/781; 174/255; 438/612; 438/121; 257/E23.001

(57) ABSTRACT

In a wiring board of a semiconductor device according to the present invention, a land 9 provided with convex portions/concave portions arranged so as to comprise finite rotation symmetry is provided on a substrate 13 of a wiring board 1, a side surface and a part of a vicinity of a periphery of a top surface of the land 9 is covered with solder resist 21b, and the solder resist 21b comprises a contact portion that is in contact with the land 9 and a non-contact portion that is not in contact with the land 9.

This application is based upon and claims the benefit of priority from Japanese patent application No. 2007-284164, filed Oct. 31, 2007, the disclosure of which is incorporated herein in its entirety by reference.

### BACKGROUND OF THE INVENTION

1. Field of the Invention

The present invention relates to: a wiring board of a semiconductor device on which a semiconductor element is mounted; a semiconductor device on which the wiring board of the semiconductor device is mounted; an electronic apparatus using the semiconductor device; a mother board comprising features of the present invention; a method of manufacturing a wiring board of a semiconductor device; a method of manufacturing a semiconductor device using the wiring board of the semiconductor device and an electronic apparatus on which the semiconductor device is mounted; a method of manufacturing a mother board; and a method of manufacturing an electronic apparatus in which semiconductors and electronic parts are mounted on the mother board.

In recent years, high integration and miniaturization of a semiconductor element utilized for an electronic apparatus proceed with miniaturization and high performance of the electronic apparatus.

For that reason, as a connection structure between a semiconductor element and a board, a structure in which a pedestal for an electrical conductor called a “land” is provided on the substrate and a contact member such as a solder ball provided on the land is connected to other board or the like may be utilized.

In such a configuration, in order to cause the semiconductor element to become further high integration and multiple terminals, it is required to cause the land and the contact member to be miniaturized.

However, there has been a problem that, because miniaturization causes an area of a contact portion between the land and the substrate, or an area of a contact portion between the land and the contact member to be reduced, joint strength thereof is to be lowered.

Therefore, it is required a structure for preventing the joint strength due to the miniaturization to be lowered.

An SMD (Solder Mask Defined) structure is known as a structure for preventing joint strength between the land and the substrate to be lowered.

The SMD structure is a structure in which solder resist is provided so as to cover a side surface and a vicinity of a periphery of a top surface of the land. Since the land is fixed by means of the solder resist, joint strength therebetween can be improved.

However, there has been a problem that a contact area between the land and the contact member is reduced and joint strength between the land and the contact member is lowered because a part of the top surface of the land is covered with the solder resist in the SMD structure.

On the other hand, an NSMD (Non Solder Mask Defined) structure is known as a structure for preventing joint strength between the land and the contact member to be lowered.

The NSMD structure is a structure in which a gap is provided between the land and the solder resist. Since the contact member gets into contact not only with the top surface of the land but also with the side surface of the land, joint strength between the land and the contact member can be improved.

However, there has been a problem that joint strength between the land and the substrate is lowered because the land is not in contact with the solder resist in the NSMD structure.

2. Description of Related Art

In order to strengthen joint between the land and the contact member, it is known a structure in which the joint strength is improved by providing a concavo-convex shape to the surface of the land.

For example, Japanese Patent Application Publication No. 11-297873 (Patent Document 1) discloses a semiconductor device in which a pedestal having concave portions and convex portions on an element body and a solder ball is provided on the pedestal. In Patent Document 1, a belt shape, a checkered shape and a concentrically circular shape are proposed as a shape of each of the concave portion and convex portion.

Further, Japanese Patent Application Publication No. 2001-223293 (Patent Document 2) discloses a ball grid array type semiconductor device in which a land portion is formed on a substrate and convex portions are provided on the land portion.

The structure in which a concavo-convex shape is provided on a surface of the land like Patent Documents 1 and 2 is a useful structure in terms of being capable of improving the joint strength between the land and the contact member such as a ball.

However, in Patent Documents 1 and 2, it has been revealed that the joint strength between the land and the substrate supporting the land is insufficient. For this reason, it is desired that not only the connection strength between the land and the contact member but also connection strength between the land and the substrate are to be improved. Further, even though the concavo-convex shape is provided on the land in the form of a belt shape, a checkered shape and a concentrically circular shape like Patent Document 1, strength against a shock from a specific direction may be insufficient, and thus, it has been insufficient to heighten reliability against a shock. This is also true in Patent Document 2.

### SUMMARY

The present invention seeks to solve one or more of the above problems, or to improve upon those problems at least in part.

In one embodiment, there is a wiring board of a semiconductor device, comprising: a substrate; a land provided on the substrate to mount a contact member; and solder resist provided so as to cover a surface of the substrate, a side surface and a vicinity of a periphery of a top surface of the land, wherein the solder resist comprises a contact portion that is in contact with the land, and a non-contact portion that is not in contact with the land.

In one embodiment, there is a method of manufacturing a wiring board of a semiconductor device, the method comprising: providing solder resist so as to partially cover a surface of a substrate, a side surface and a vicinity of a periphery of a top surface of a land on the substrate, wherein the providing solder resist comprises processing the solder resist so as to comprise a contact portion that is in contact with the land and a non-contact portion that is not in contract with the land.

In one embodiment, there is a method of manufacturing a wiring board of a semiconductor device, the method comprising: forming a land by forming a metallic thin film on a substrate and then subjecting the metallic thin film to selective etching; and forming a plurality of concave portions and/or convex portions provided so as to comprise three times or more of finite rotation symmetry on the land with respect to the center of the land by further subjecting a surface of the metallic thin film to selective etching.

Effects of the Invention:

According to the present invention, it is possible to improve joint strength between a land and a substrate, and joint strength between the land and a contact member compared with a conventional case. In addition, it is possible to provide a wiring board and a semiconductor device whose reliability against a shock is superior to a conventional case, a mother board, and an electronic apparatus on which they are mounted.

### BRIEF DESCRIPTION OF THE DRAWINGS

The above features and advantages of the present invention will be more apparent from the following description of certain preferred embodiments taken in conjunction with the accompanying drawings, in which;

FIG. 1 is a sectional view showing a semiconductor device 3;

FIG. 2 is an arrow view from a point 2 of FIG. 1;

FIG. 3 is an enlarged view of an area 100 of FIG. 2 in which an indication of the solder ball 11 is omitted, an exposed portion of a land 9 is displayed by means of stipple, and a portion of a periphery of the land 9 that is covered with the solder resist 21b is displayed by means of a dotted line;

FIG. 4A is a sectional view taken along the line 4A-4A of FIG. 3;

FIG. 4B is a sectional view taken along the line 4B-4B of FIG. 3;

FIG. 5A is a sectional view of the case of comprising the solder ball 11 taken along the line 4A-4A of FIG. 3;

FIG. 5B is a sectional view of the case of comprising the solder ball 11 taken along the line 4B-4B of FIG. 3;

FIG. 6 is a plan view showing a wiring mother board 35;

FIG. 7A is a view showing procedures of manufacturing the wiring mother board 35;

FIG. 7B is a view showing procedures of manufacturing the wiring mother board 35;

FIG. 7C is a view showing procedures of manufacturing the wiring mother board 35;

FIG. 8A is a view showing procedures of manufacturing the wiring mother board 35;

FIG. 8B is a view showing procedures of manufacturing the wiring mother board 35;

FIG. 8C is a view showing procedures of manufacturing the wiring mother board 35;

FIG. 9A is a view showing procedures of manufacturing the semiconductor device 3 using the wiring mother board 35;

FIG. 9B is a view showing procedures of manufacturing the semiconductor device 3 using the wiring mother board 35;

FIG. 9C is a view showing procedures of manufacturing the semiconductor device 3 using the wiring mother board 35;

FIG. 10A is a view showing procedures of manufacturing the semiconductor device 3 using the wiring mother board 35;

FIG. 10B is a view showing procedures of manufacturing the semiconductor device 3 using the wiring mother board 35;

FIG. 11 is a sectional view showing an electronic apparatus 101;

FIG. 12A is a plan view showing a wiring board la in which an indication of the solder ball 11 is omitted, an exposed portion of the land 9 is displayed by means of stipple, and a portion of a periphery of the land 9 that is covered with the solder resist 21b is displayed by means of a dotted line;

FIG. 12B is a sectional view taken along the line 12B-12B of FIG. 12A;

FIG. 13 is a plan view showing a wiring board 1b in which an indication of the solder ball 11 is omitted, an exposed portion of a land 9 is displayed by means of stipple, and a portion of a periphery of the land 9 that is covered with the solder resist 21b is displayed by means of a dotted line;

FIG. 14A is a plan view showing a wiring board 1c in which an indication of the solder ball 11 is omitted, an exposed portion of a land 9 is displayed by means of stipple, and a portion of a periphery of the land 9 that is covered with the solder resist 21b is displayed by means of a dotted line;

FIG. 14B is a plan view showing variation of FIG. 14A; and

FIG. 15 is a plan view showing a wiring board 1d in which an indication of the solder ball 11 is omitted, an exposed portion of a land 9 is displayed by means of stipple, and a portion of a periphery of the land 9 that is covered with the solder resist 21b is displayed by means of a dotted line.

### DETAILED DESCRIPTION OF PREFERRED EMBODIMENTS

The invention will now described herein with reference to illustrative embodiments. Those skilled in the art will recognize that many alternative embodiments can be accomplished using the teachings of the present invention and that the invention is not limited to the embodiments illustrated for explanatory purposes.

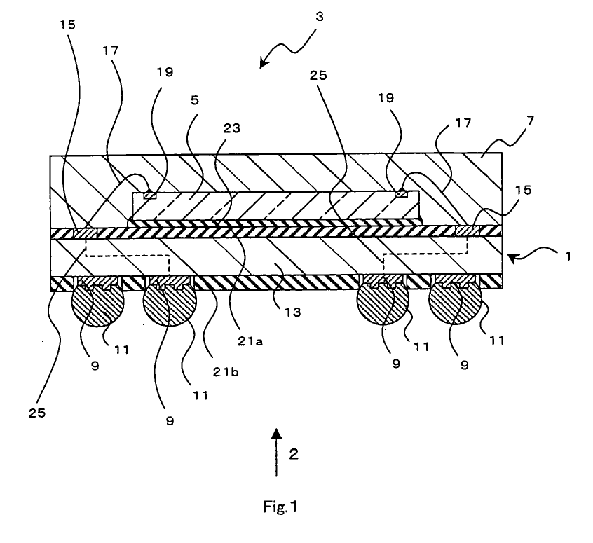

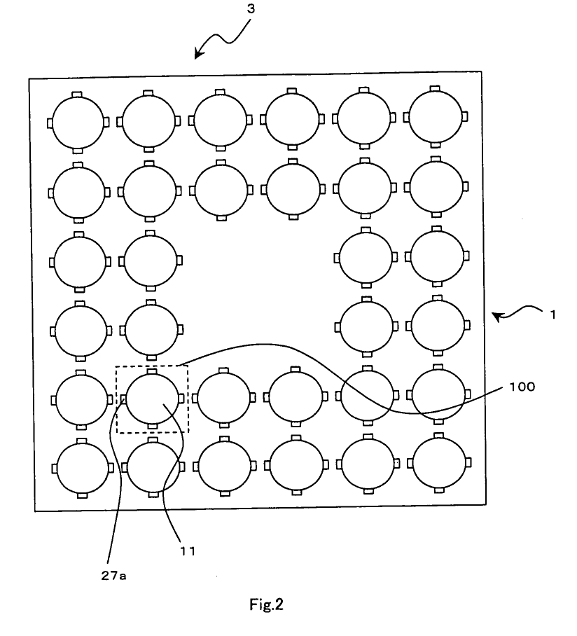

Schematic configurations of a wiring board 1 and a semiconductor device 3 comprising the wiring board according to a first embodiment of the present invention will first be described with reference to FIGS. 1 and 2.

Referring now to FIGS. 1 and 2, the semiconductor device 3 comprises a slate-shaped wiring board 1 whose planar shape is substantially a quadrangle, and a semiconductor chip 5. The shown semiconductor chip 5 is mounted on one surface of the wiring board 1.

The semiconductor chip 5 is provided with, for example, a logic circuit such as a microprocessor or a memory circuit such as an SRAM (Static Random Access Memory) and a DRAM (Dynamic Random Access Memory) and the like on one surface of the substrate made of a material of a semiconductor chip such as silicon and germanium.

A solder ball 11 for connecting the semiconductor device 3 to other devices is provided on the other surface of the wiring board 1 as a contact member.

The configurations of the wiring board 1 and the semiconductor device 3 will be described further in detail with reference to FIGS. 1 and 2.

As shown in FIGS. 1 and 2, the wiring board 1 comprises: a substrate 13; solder resist 21a provided on one surface of the substrate 13 on which the semiconductor chip 5 is mounted; solder resist 21b provided on the other surface of the substrate 13; lands 9 provided on the other surface of the substrate 13; connection pads 15 provided on the one surface of the substrate 13 on which the semiconductor chip 5 is mounted, and wiring 25 provided inside the substrate 13.

To be described concretely, the substrate 13 of the wiring board 1 is made of glass epoxy or the like, and the connection pads 15 are provided in the vicinity of a periphery of the one surface of the substrate 13.

The solder resist 21a provided on the one side of the substrate 13 on which the semiconductor chip 5 is mounted is provided at an area other than an area for forming the connection pads 15.

The semiconductor chip 5 is provided on the solder resist 21a via an adhesive 23 made of an insulating material.

A plurality of electrode pads 19 for connection to the connection pads 15 are provided on the surface of the semiconductor chip 5, and the connection pads 15 are electrically connected to the respective electrode pads 19 by means of wires 17.

In this regard, a passivation film (not shown in the drawings) is formed on the surface of the semiconductor chip 5 except for the electrode pads 19 to protect a circuit formation surface.

Further, a sealing portion 7 is provided so as to cover at least the semiconductor chip 5, the connection pads 15, the electrode pads 19 and the wires 17.

The sealing portion 7 is made of an insulating thermosetting resin such as an epoxy resin to protect the semiconductor chip 5, the connection pads 15 that are electrically connecting portions, the electrode pads 19 and the wires 17.

On the other hand, the lands 9 provided on the other surface side of the substrate 13 are arranged in a grid manner at predetermined intervals. Further, each of the lands 9 is electrically connected to the corresponding connection pad 15 via the wiring 25 provided in the substrate 13.

Namely, each of the lands 9 is electrically connected to the corresponding electrode pad 19 of the semiconductor chip 5 via the wiring 25 and the connection pad 15.

Further, the solder resist 21b, as will be described later, is provided on the other surface of the substrate 13 so as to partially cover a part of a central area and a periphery of each of the lands 9. Moreover, the solder ball 11 as the contact member is provided on each of the lands 9.

The solder ball 11 is connected to a connecting portion, such as a land, of other device, whereby the semiconductor chip 5 is electrically connected to the other device.

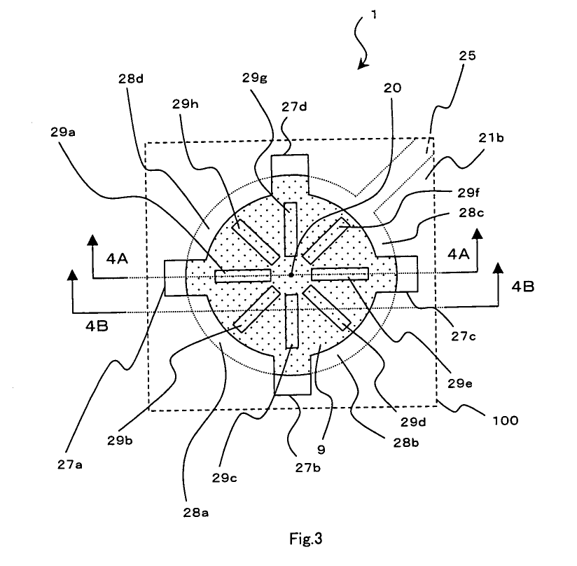

Next, a configuration of the wiring board 1 in the vicinity of the land 9 will be described with reference to FIGS. 3 to 5B.

In this regard, in FIG. 3, a stippled portion is a portion of the land 9 that is not covered with the solder resist 21b, while a portion indicated by a dotted line is a portion of a periphery of the land 9 that is covered with the solder resist 21b.

The land 9, as will be described later, is formed by subjecting a thin film of an electrical conductor made of Cu or the like to etching so as to become a desired pattern shape, and as shown in FIG. 3, in the first embodiment, the land 9 is formed in a substantially circular shape.

Further, the surface of the substrate 13 (see FIG. 1) and most of the side surface and the vicinity of the periphery of the top surface of the land 9 are covered with the solder resist 21b. Furthermore, portions of the solder resist 21b, which cover the side surface and the vicinity of the periphery of the top surface of the land 9, that is, portions that are in contact with the land 9 constitute contact portions 28a, 28b, 28c, 28d.

On the other hand, in the solder resist 21b, portions that are not in contact with the land 9 constitute notch portions 27a, 27b, 27c, and 27d as non-contact portions.

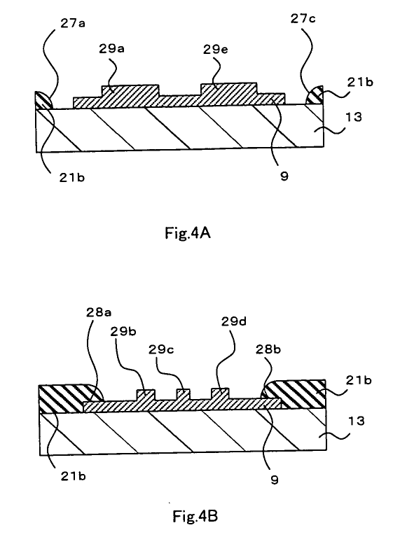

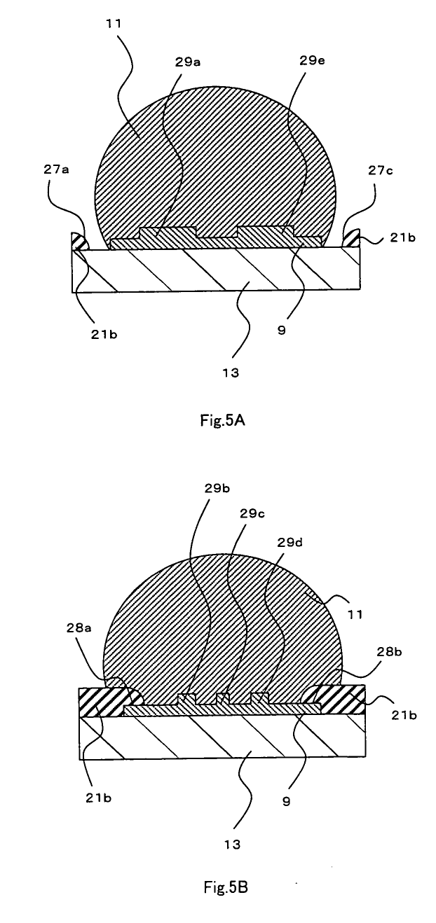

Here, when the sectional view in the vicinity of the land 9 shown in FIGS. 4A to 5B is seen, as shown in FIG. 4A, the solder resist 21b is not in contact with the land 9 in portions at which the notch portions 27a, 27c are provided to form a so-called NSMD (Non Solder Mask Defined) structure.

For that reason, when the solder ball 11 is provided, as shown in FIG. 5A, the solder ball 11 gets into contact not only with the top surface of the land 9, but also with the side surface of the land 9, whereby joint strength between the land 9 and the solder ball 11 can be improved compared with the case where the solder ball 11 is in contact with only the top surface.

Portions at which the notch portion 27b, 27d are provided are also similar to the portions at which the notch portion 27a, 27c are provided.

On the other hand, in portions at which the contact portion 28a, 28b are provided, as shown in FIG. 4B, the side surface and the vicinity of the periphery of the top surface of the land 9 are in contact with the solder resist 21b to form a so-called SMD (Solder Mask Defined) structure. For that reason, joint strength between the substrate 13 and the land 9 can be improved. Portions at which the contact portions 28c, 28d are provided are also similar to the portions at which the contact portions 28a, 28b are provided.

In this way, since the shown wiring board 1 comprises both structures of the NSMD structure and the SMD structure, not only the joint strength between the land 9 and the solder ball 11 can be improved, but also the joint strength between the land 9 and the substrate 13 can be improved.

In this regard, in order to secure stable joint strength and to improve joint strength against a shock from any direction in a planar direction, it is preferable that the notch portions 27a, 27b, 27c, 27d are arranged so as to comprise three times or more of finite rotation symmetry in which the notch portions 27a, 27b, 27c, 27d are disposed at regular intervals with respect to the center 20 of the land 9. As shown in FIG. 3, it is more preferable that they are arranged so as to comprise four times or more of finite rotation symmetry. Further, of the rotation symmetry, as shown in FIG. 3, it is preferable to provide the notch portions 27a, 27b, 27c, and 27d radially from the center 20 of the land 9. In this regard, in FIG. 3, the notch portions 27a, 27b, 27c, 27d are arranged so as to comprise four times of rotation symmetry.

Further, it is preferable that the wiring 25 to be connected to the land 9 is connected to the land 9 at a position other than the notch portions 27a, 27b, 27c, and 27d. This is because the wiring 25 is exposed to the outside when the wiring 25 is arranged at a position at which the wiring 25 is overlapped with the notch portions 27a, 27b, 27c, and 27d.

Moreover, as shown in FIGS. 3, 4A and 4B, a plurality of convex portions 29a, 29b, 29c, 29d, 29e, 29f, 29g, 29h (here, eight) are formed on the top surface of the land 9 to expand a contact area between the land 9 and the solder ball 11. As shown in FIG. 3, the convex portions 29a, 29b, 29c, 29d, 29e, 29f, 29g, 29h are arranged radially with respect to the center of the land 9 so as to comprise eight times of rotation symmetry with respect to the center 20 of the land 9.

In this regard, it is preferable that the convex portions are arranged so as to comprise three times or more of finite rotation symmetry in which the convex portions are disposed at least at regular intervals with respect to the center 20 of the land 9, and it is more preferable that the convex portions are arranged so as to comprise four times or more of finite rotation symmetry. Moreover, as shown in FIG. 3, it is further more preferable that the convex portions are arranged radially with respect to the center 20 of the land 9.

In the shown convex portions 29a, 29b, 29c, 29d, 29e, 29f, 29g, 29h, a planar shape thereof is a rectangle, and the convex portions are provided so that a longitudinal direction of each of the convex portions is directed to a radial direction from the center 20 of the land 9.

By providing the convex portions 29a, 29b, 29c, 29d, 29e, 29f, 29g, 29h on the top surface of the land 9 in this way, it is possible to cause the contact area between the land 9 and the solder ball 11 to become larger, and it is possible to improve joint strength between the land 9 and the solder ball 11.

Further, by providing the convex portions 29a, 29b, 29c, 29d, 29e, 29f, 29g, 29h so as to comprise three times or more (preferably, four times of more) of finite rotation symmetry, in which the convex portions 29a, 29b, 29c, 29d, 29e, 29f, 29g, 29h are radially disposed at regular intervals with respect to the center 20 of the land 9, it is possible to improve the joint strength between the land 9 and the solder ball 11 against a shock from any direction in a planar direction, and it is possible to heighten reliability against a shock compared with a conventional case.

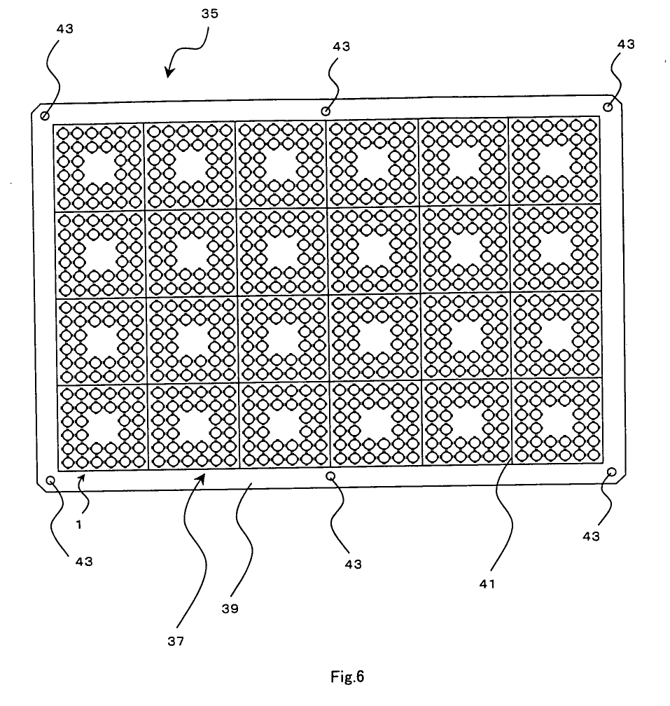

Next, a method of manufacturing a semiconductor device 3 comprising the wiring board 1 described above will be described with reference to FIGS. 6 to 10B.

The semiconductor device 3 is manufactured by manufacturing a wiring mother board 35 comprising a plurality of wiring boards 1 first, and arranging a semiconductor chip 5 and the like on the wiring mother board 35 next.

Procedures of manufacturing the wiring mother board 35 will first be described with reference to FIGS. 6 to 8C.

At the beginning, a configuration of the wiring mother board 35 will be described with reference to FIG. 6.

As shown in FIG. 6, the wiring mother board 35 comprises a plurality of rectangular product formed areas 37.

The product formed areas 37 are arranged in a matrix manner, and dicing lines 41 as cutoff lines are formed between the adjacent product-formed areas 37.

The wiring boards 1 are formed by carrying out predetermined processes (formation of lands 9 and solder resist 21b, will be described later) to the product formed areas 37.

Further, a frame portion 39 is formed around the product formed areas 37. When the wiring mother board 35 is to be moved, the frame portion 39 is carried while a carrying apparatus (not shown in the drawings) is caused to get into contact with the frame portion 39.

By forming the frame portion 39 in this way, it is possible to move the wiring mother board 35 without contact with the product formed areas 37.

Further, a plurality of locating holes 43 are provided in the frame portion 39, and utilized for locating at movement.

Next, procedures of forming a wiring mother board 35 will be described with reference to FIGS. 1, 3 and 6 to 8C.

A substrate 13 made of glass epoxy or the like is first prepared, and the substrate 13 is formed so as to become a planar shape similar to that of the wiring mother board 35 (FIG. 6).

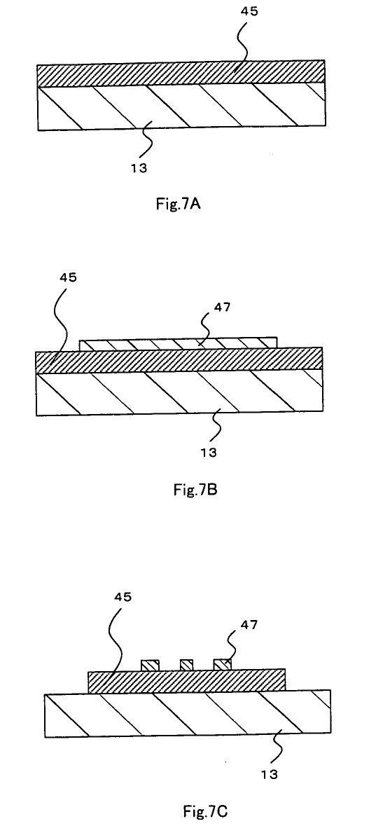

Next, as shown in FIG. 7A, a copper layer 45 for forming a land 9 is stuck onto the substrate 13. Next, photoresist 47 that is a resist film is applied to a surface of the copper layer 45. After applying the photoresist 47, as shown in FIG. 7B, by patterning the photoresist 47 and removing the photoresist 47 other than a portion for forming the land 9 and a wiring pattern (not shown in the drawings), a removed portion of the copper layer 45 is exposed. Moreover, by subjecting the exposed portion of the copper layer 45 to etching, a desired planar shape of the land and a wiring pattern (not shown in the drawings) are formed.

Moreover, by patterning the photoresist 47 on the copper layer 45 to a desired shape, as shown in FIG. 7C, the photoresist 47 is caused to remain at only portions for forming convex portions.

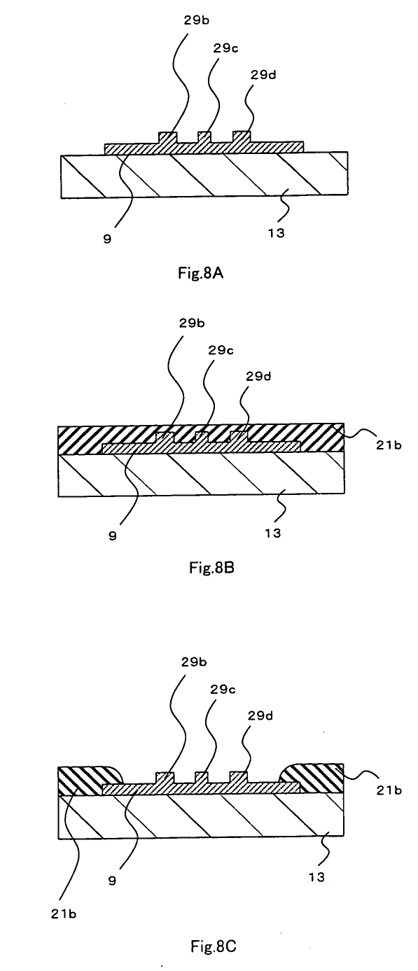

Next, as shown in FIG. 8A, by subjecting the copper layer 45 to selective etching, convex portions 29b, 29c, and 29d are formed, and the remaining photoresist 47 is removed. In this regard, although it is not shown in the drawings, convex portions 29a, 29e, 29f, 29g, 29h are also formed in the same manner.

By the steps described above, a land 9 comprising the convex portions is formed on the substrate 13.

When the land 9 is formed, as shown in FIG. 8B, ultraviolet curable solder resist 21b is next applied to the whole surface of the substrate 13 and the land 9.

When application of the solder resist 21b is completed, only portions of the solder resist 21b to be desired to remain are irradiated with ultraviolet rays to be cured.

Here, as described above, the solder resist 21b comprises the contact portions 28a, 28b, 28c, 28d that are in contact with the side surface and the vicinity of the periphery of the top surface of the land 9, and the non-contact portions (notch portions 27a, 27b, 27c, 27d) that are not in contact with the land 9.

Thus, areas to provide the contact portions 28a, 28b, 28c, 28d are to be irradiated with ultraviolet rays, while areas to provide the notch portions 27a, 27b, 27c, 27d are not irradiated with ultraviolet rays.

In this regard, an area at which the land 9 is not provided is also irradiated with ultraviolet rays.

By washing the whole surface of the substrate 13 and the land 9 after irradiation of ultraviolet rays to remove the solder resist 21b from uncured portions, a structure as shown in FIG. 8C is formed.

Namely, the solder resist 21b is formed so as to cover most of the side surface and the vicinity of the periphery of the top surface of the land 9, and comprises the contact portions 28a, 28b, 28c, 28d that are in contact with the land 9 and the notch portions 27a, 27b, 27c, 27d that are not in contact with the land 9 (see FIG. 3).

Here, at the step described above, since the convex portions 29b, 29c, 29d are formed from the copper layer 45 by means of etching, the convex portions 29b, 29c, 29d are integrally formed with the land 9.

Thus, good joint strength can be secured compared with the case where convex portions are laminated and formed after formation of the land 9 separately.

Next, if necessary, solder resist 21a and connection pads 15 as shown in FIG. 1 are formed on the other side surface of the substrate 13, and wiring 25 for connecting the connection pad 15 to the land 9 is provided in the substrate 13, whereby a wiring mother board 35 is completed.

In this regard, the surface of the land and the surface of the connection pad are subjected to plate processing if necessary, whereby they can comprise effects of inhibited oxidation, a barrier and the like.

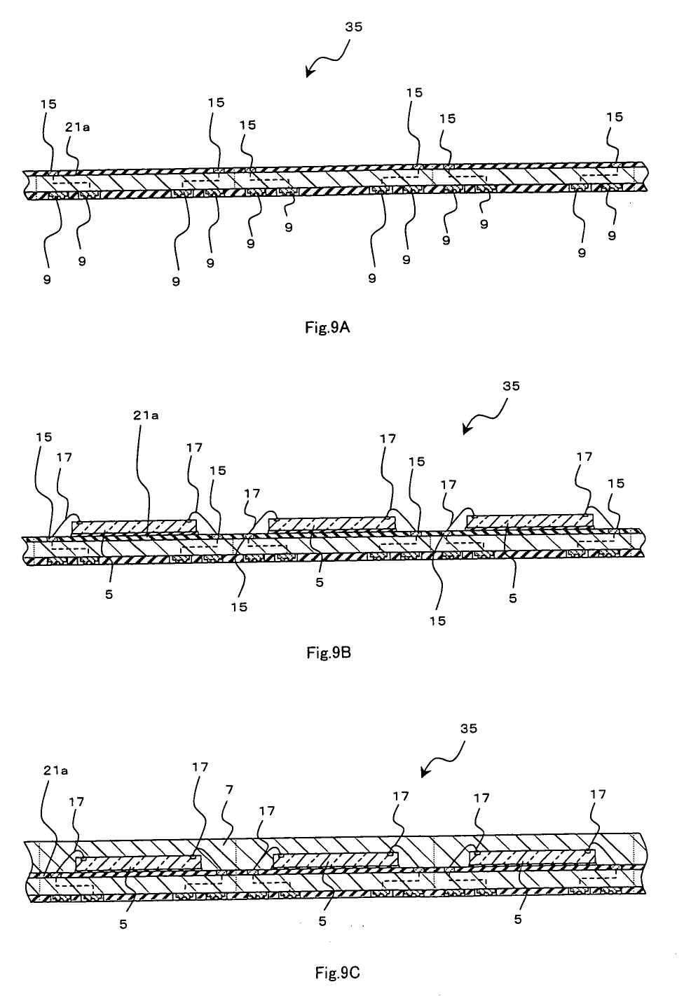

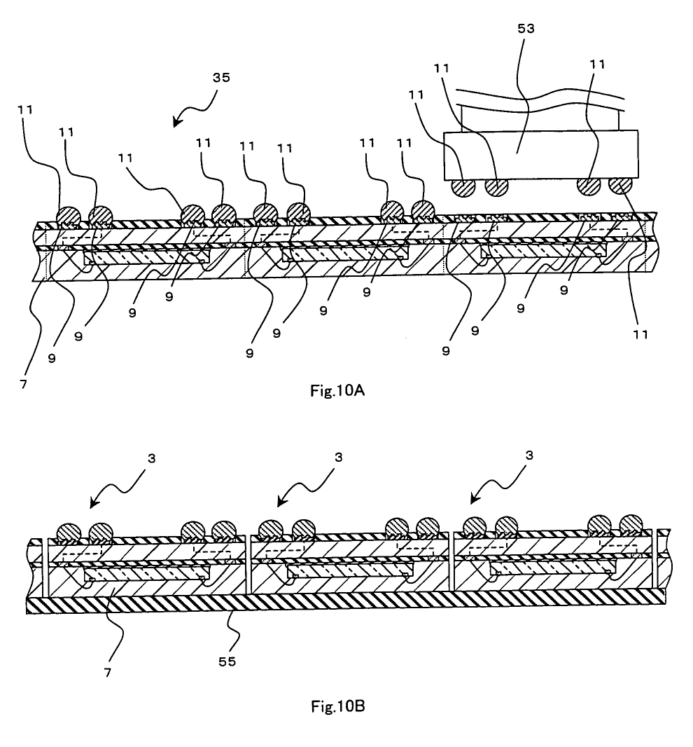

Next, procedures of manufacturing the semiconductor device 3 by arranging the semiconductor chip 5 on the wiring mother board 35 will be described with reference to FIGS. 9A to 10B.

As shown in FIG. 9A, the wiring mother board 35 is mounted on a chip mounting apparatus (not shown in the drawings) so that the connection pads 15 turn up.

When mounting of the wiring mother board 35 is completed, as shown in FIG. 9B, the semiconductor chips 5 are mounted on adhesives applied onto the solder resist 21a using a chip mounting apparatus (not shown in the drawings), and then, the adhesives are cured by application of heat, whereby chip mounting is completed.

When mounting of the semiconductor chips 5 is completed, they are mounted on a wire bonder apparatus (not shown in the drawings).

A wire bonder apparatus connects one end of a wire 17 to the electrode pad 19 (see FIG. 1) by thermo-ultrasonic bonding, and then connects the other end onto the connection pad 15 by thermo-ultrasonic bonding while drawing a predetermined loop shape.

Next, the wiring mother board 35 on which the semiconductor chips 5 are mounted is mounted on a molding apparatus (not shown in the drawings).

When mounting of the wiring mother board 35 is completed, at the state where the wiring mother board 35 is confined to a mold by an upper mold and a lower mold of the molding apparatus (not shown in the drawings), the mold is filled with a molten sealing resin, for example, a thermosetting epoxy resin or the like, and the molten sealing resin is cured at the filled state.

Then, the sealing resin is thermally cured, as shown in FIG. 9C, a sealing portion 7 that collectively covers a plurality of product formed areas 37 (see FIG. 6) is formed. By utilizing collective molding, the sealing portion 7 can be formed effectively.

Next, the wiring mother board 35 is mounted on a ball mounting apparatus (not shown in the drawings) so that the lands 9 turn up.

When mounting of the wiring mother board 35 is completed, as shown in FIG. 10A, for example, solder balls 11 are caused to adhere to a mounting tool 53 of the ball mounting apparatus in vacuum, and the solder balls 11 are mounted on the land 9 via a flux.

Then, by causing the wiring mother board 35 to reflow, the solder balls 11 are connected to the land 9.

By mounting the solder balls 11 on the lands 9 of the wiring mother board 35 in this manner, external terminals (contact members) are formed.

Next, the wiring mother board 35 is mounted on a plate dicing apparatus (not shown in the drawings).

Specifically, as shown in FIG. 10B, the sealing portion 7 is stuck and fixed to a dicing tape 55.

Next, by rotationally grinding dicing lines 41 (see FIG. 6) of the stuck and fixed wiring mother board 35 by means of a dicing blade (not shown in the drawings), the wiring mother board 35 is cut and separated into individual product formed areas 37 (see FIG. 6).

Finally, by picking up the separated individual product formed areas 37 from the dicing tape 55, semiconductor devices 3 as shown in FIG. 1 are obtained.

Thus, according to the first embodiment, the wiring board 1 of the semiconductor device 3 comprises the substrate 13, the solder resist 21b and the land 9, and the solder resist 21b comprises the contact portions 28a, 28b, 28c, 28d that are in contact with the land 9 and the notch portions 27a, 27b, 27c, 27d that are not in contact with the land 9.

For that reason, since the wiring board 1 comprises both structures of an NSMD structure and an SMD structure, it is possible to achieve a balance of improving joint strength between the land 9 and the solder ball 11 and improving joint strength between the land 9 and the substrate 13.

Further, since the notch portions 27a, 27b, 27c, 27d that are not in contact with the land 9 are radially arranged so as to comprise three times or more of finite rotation symmetry with respect to the center 20 of the land 9, it is possible to improve joint strength between the land 9 and the solder ball 11 against a shock from any direction in a planar direction, and it is possible to heighten reliability against a shock compared with a conventional case.

Moreover, in the first embodiment, the land 9 comprises the convex portions 29a, 29b, 29c, 29d, 29e, 29f, 29g, 29h radially provided so as to comprise three times or more (here, eight times) of rotation symmetry with respect to the center 20 of the land 9 on the surface of the land 9.

For that reason, it is possible to cause a contact area between the land 9 and the solder ball 11 to become larger, and it is possible to improve joint strength compared with a conventional case.

Further, since the convex portions 29a, 29b, 29c, 29d, 29e, 29f, 29g, 29h are radially arranged so as to comprise three times or more of finite rotation symmetry (here, eight times) with respect to the center 20 of the land 9, it is possible to improve joint strength between the land 9 and the solder ball 11 against a shock from any direction in a planar direction, and it is possible to heighten reliability against a shock compared with a conventional case.

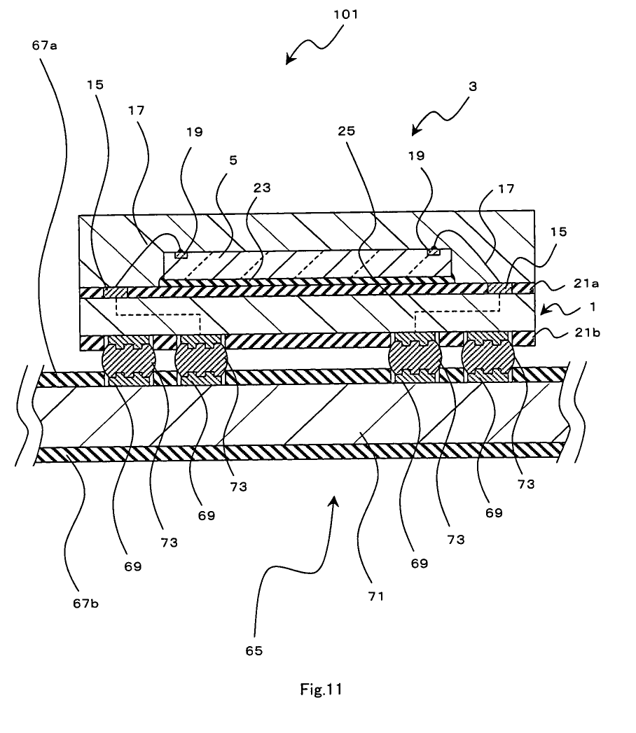

Next, an electronic apparatus 101 according to a second embodiment will be described with reference to FIG. 11.

The electronic apparatus 101 according to the second embodiment is one in which the semiconductor device 3 according to the first embodiment is implemented on a mother board 65.

In this regard, in the second embodiment, elements that fulfill the similar functions to those in the first embodiment are denoted by the same reference numerals and detailed descriptions thereof are omitted.

As shown in FIG. 11, the electronic apparatus 101 comprises the mother board 65 and the semiconductor device 3.

The mother board 65 comprises a substrate 71 made of glass epoxy or the like, and a plurality of lands 69 are arranged on one surface of the substrate 71 in a grid manner at predetermined intervals.

Further, on the one surface of the substrate 71, solder resist 67a is provided except for a central area and a part of a periphery of each of the lands 69, and solder resist 67b is provided on the other surface.

The structure of the solder resist 67a and the structure of the land 69 are respectively similar to the structure of the solder resist 21b of the wiring board 1 of the semiconductor device 3 and the structure of the land 9.

Namely, contact portions that are in contact with the lands 69 and notch portions that are not in contact with the lands 69 are provided in the solder resist 67a. As explained in connection with the first embodiment, a plurality of the notch portions are radially arranged so as to comprise three times or more of finite rotation symmetry with respect to the center 20 of the land 9.

Further, a plurality of convex portions are formed on a top surface of the land 69, and the plurality of convex portions are radially arranged so as to comprise three times or more of finite rotation symmetry with respect to the center 20 of the land 9.

The lands 69 of the mother board 65 are electrically connected to the lands 9 of the wiring board 1 of the semiconductor device 3 via solder balls 73 as the contact members, respectively.

In this way, the land 69 and the solder resist 67a comprising the similar structures to those in the wiring board 1 may be provided not only in the semiconductor device 3 but also in the mother board 65 that is a connection object.

By comprising such a structure, even in the mother board 65, it is possible to improve joint strength between the land 69 and the substrate 71, or joint strength between the land 69 the solder ball 73, and it is possible to provide improvement on reliability against a shock from a horizontal direction.

Thus, according to the second embodiment, the electronic apparatus 101 comprises the mother board 65 and the semiconductor device 3.

Therefore, it is possible to achieve the effect similar to or more than that in the first embodiment.

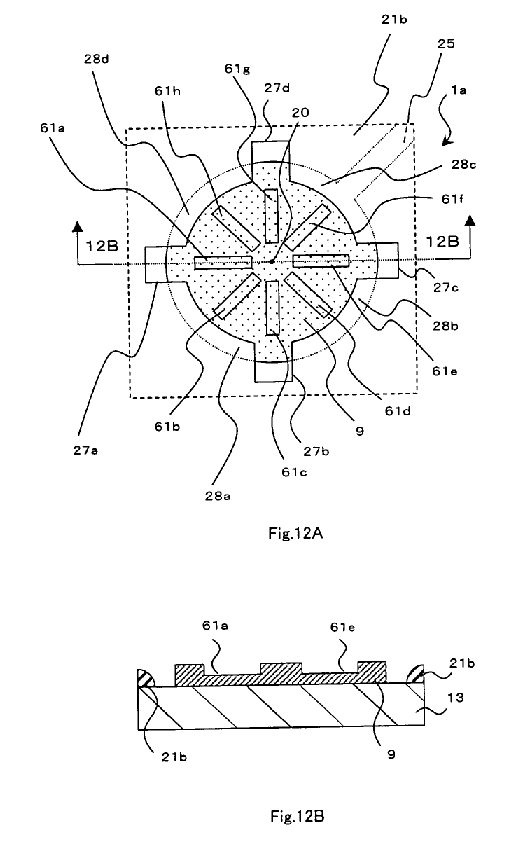

Next, a wiring board la according to a third embodiment will be described with reference to FIGS. 12A and 12B.

The wiring board 1a according to the third embodiment is one in which concave portions are provided on a top surface of the land 9 in place of the convex portions in the first embodiment.

In this regard, in the third embodiment, elements that fulfill the similar functions to those in the first embodiment are denoted by the same reference numerals and detailed descriptions thereof are omitted.

As shown in FIGS. 12A and 12B, concave portions 61a, 61b, 61c, 61d, 61e, 61f, 61g, 61h are formed on a surface of the land 9 of the wiring board 1a.

The concave portions 61a, 61b, 61c, 61d, 61e, 61f, 61g, 61h are radially arranged so as to comprise eight times of rotation symmetry with respect to the center 20 of the land 9.

In this way, the concave portions may be provided on the surface of the land 9 in place of the convex portions.

Thus, according to the third embodiment, the wiring board 1a comprises the lands 9 and the solder resist 21b, and the solder resist 21b comprises the contact portions 28a, 28b, 28c, 28d and the notch portions 27a, 27b, 27c, 27d.

Further, the concave portions 61a, 61b, 61c, 61d, 61e, 61f, 61g, 61h are formed on the surface of the land 9.

Therefore, it is possible to achieve the effect similar to that in the first embodiment.

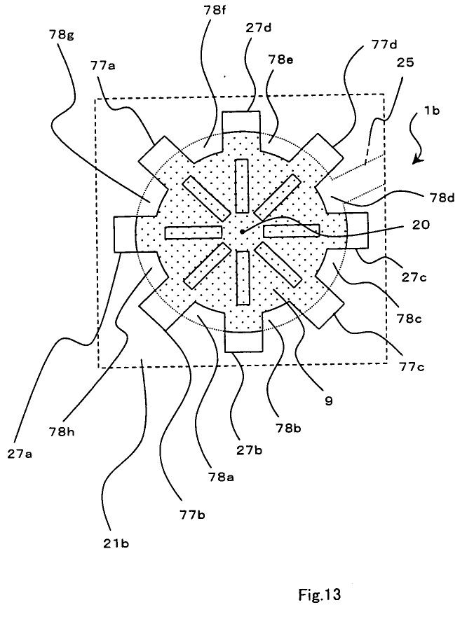

Next, a wiring board 1b according to a fourth embodiment will be described with reference to FIG. 13.

The wiring board 1b according to the fourth embodiment is one in which the number of notch portions is increased compared with the first embodiment.

In this regard, in the fourth embodiment, elements that fulfill the similar functions to those in the first embodiment are denoted by the same reference numerals and detailed descriptions thereof are omitted.

As shown in FIG. 13, solder resist 21b on the wiring board 1b further comprises notch portions 77a, 77b, 77c, 77d that are not in contact with a land 9 as non-contact portions in addition to notch portions 27a, 27b, 27c, 27d.

The notch portions 77a, 77b, 77c, 77d are provided radially from the center 20 of the land 9 toward a periphery of the land 9 as well as the notch portions 27a, 27b, 27c, 27d.

Further, the solder resist 21b comprises contact portions 78a, 78b, 78c, 78d, 78e, 78f, 78g, 78h that are in contact with the side surface and the vicinity of the periphery of the top surface of the land 9.

The contact portion 78a is provided between the notch portion 77b and the notch portion 27b, and the contact portion 78b is provided between the notch portion 77c and the notch portion 27b. The contact portion 78c is provided between the notch portion 77c and the notch portion 27c, and the contact portion 78d is provided between the notch portion 77d and the notch portion 27c. The contact portion 78e is provided between the notch portion 77d and the notch portion 27d, and the contact portion 78f is provided between the notch portion 77a and the notch portion 27d. The contact portion 78g is provided between the notch portion 77a and the notch portion 27a, and the contact portion 78h is provided between the notch portion 77b and the notch portion 27a.

The number of notch portions may be increased in this way compared with the first embodiment. By comprising such a structure, it is possible to further improve the joint strength between the land 9 and the solder ball 11.

Thus, according to the fourth embodiment, the number of notch portions may be increased compared with the first embodiment, the solder resist 21b further comprises the notch portions 77a, 77b, 77c, 77d in addition to the notch portions 27a, 27b, 27c, 27d, and the whole notch portions are radially arranged so as to comprise eight times of rotation symmetry with respect to the center 20 of the land 9. By comprising such a structure, it is possible to improve joint strength between the land 9 and the solder ball 11 further, and it is possible to provide a semiconductor device whose reliability against a shock from a horizontal direction is further superior.

Therefore, it is possible to achieve the effect similar to or more than that in the first embodiment.

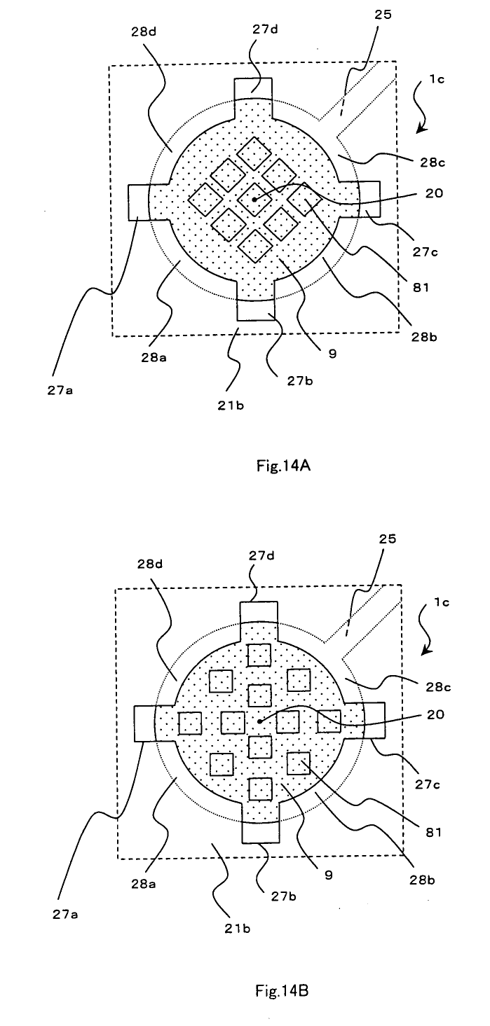

Next, a wiring board 1c according to a fifth embodiment will be described with reference to FIGS. 14A and 14B.

The wiring board 1c according to the fifth embodiment is one in which convex portions of each of which a planar shape is not a rectangular shape but a square shape are provided on a surface of a land 9 in the first embodiment.

In this regard, in the fifth embodiment, elements that fulfill the similar functions to those in the first embodiment are denoted by the same reference numerals and detailed descriptions thereof are omitted.

As shown in FIG. 14A, on a surface of the land 9 of the wiring board 1c, a plurality of convex portions 81 of each of which a planar shape is not a rectangular shape but a square shape are provided.

The convex portions 81 are arranged so that an arrangement pattern thereof becomes three times or more of finite rotation symmetry (here, four times) with respect to the center 20 of the land 9.

Thus, the convex portions 81 of each of which a planar shape is not a rectangular but a square shape may be provided on the surface of the land 9.

In this regard, although the convex portions 81 are provided so that corners of each of the convex portions 81 face the corresponding notch portions in FIG. 14A, they may be provided so that sides of each of the convex portions 81 face the corresponding notch portions as shown in FIG. 14B.

Thus, according to the fifth embodiment, the wiring board 1c comprises the land 9 and the solder resist 21b, and the solder resist 21b comprises the contact portions 28a, 28b, 28c, 28d and the notch portions 27a, 27b, 27c, 27d.

Further, the convex portions 81 are formed on the surface of the land 9.

Therefore, it is possible to achieve the effect similar to or more than that in the first embodiment.

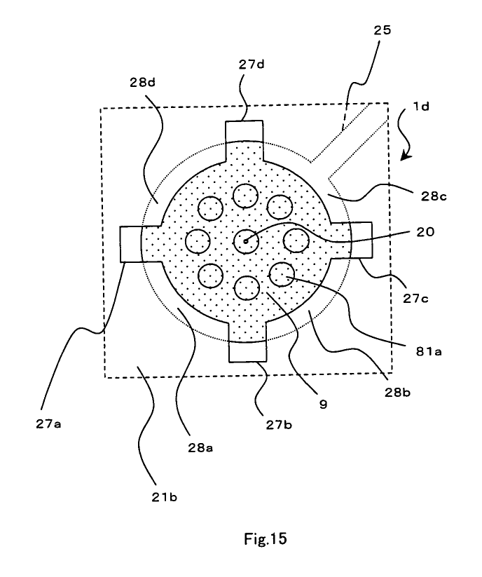

Next, a wiring board 1d according to a sixth embodiment will be described with reference to FIG. 15.

The wiring board 1d according to sixth embodiment is one in which convex portions of each of which a planar shape is not a rectangular shape but a circular shape are provided on a surface of a land 9 in the first embodiment.

In this regard, in the sixth embodiment, elements that fulfill the similar functions to those in the first embodiment are denoted by the same reference numerals and detailed descriptions thereof are omitted.

As shown in FIG. 15, on a surface of the land 9 of the wiring board 1d, a plurality of convex portions 81a of each of which a planar shape is not a rectangular shape but a circular shape are provided.

The convex portions 81a are arranged so that an arrangement pattern becomes three times or more of finite rotation symmetry (here, eight times) with respect to the center 20 of the land 9.

In this way, the convex portions 81a whose planar shape is not a rectangular shape but a circular shape may be provided on the surface of the land 9.

Thus, according to the sixth embodiment, the wiring board 1d comprises the land 9 and the solder resist 21b, and the solder resist 21b comprises the contact portions 28a, 28b, 28c, 28d and the notch portions 27a, 27b, 27c, 27d.

Further, the convex portions 81a are formed on the surface of the land 9.

Therefore, it is possible to achieve the effect similar to or more than that in the first embodiment.

It is apparent that the present invention is not limited to the above embodiments, but may be modified and changed without departing from the scope and spirit of the invention.

What is claimed is:

1. A wiring board of a semiconductor device, comprising:
a substrate;
a land provided on the substrate to mount a contact member; and
solder resist provided so as to cover a surface of the substrate, a side surface and a vicinity of a periphery of a top surface of the land,
wherein the solder resist comprises a contact portion that is in contact with the land, and a non-contact portion that is not in contact with the land.

2. The wiring board of the semiconductor device as claimed in claim 1, wherein a plurality of the non-contact portions are provided so as to comprise three times or more of finite rotation symmetry with respect to the center of the land.

3. The wiring board of the semiconductor device as claimed in claim 2, wherein the non-contact portions comprise a plurality of notch portions extending radially with respect to the center of the land.

4. The wiring board of the semiconductor device as claimed in claim 1, wherein the contact member mounted on the land comprises a portion that is in contact with a side surface of the land at the non-contact portion of the solder resist.

5. The wiring board of the semiconductor device as claimed in claim 1, wherein the land comprises a plurality of concave portions and/or convex portions provided on a surface of the land, and the concave portions and/or the convex portions are arranged so as to comprise three times or more of finite rotation symmetry with respect to the center of the land.

6. The wiring board of the semiconductor device as claimed in claim 5, wherein the concave portions and/or the convex portions are provided radially from the center of the land toward a periphery of the land.

7. The wiring board of the semiconductor device as claimed in claim 5, wherein each of the concave portions and/or the convex portions comprises any planar shape of a round shape, a rectangular shape and a polygonal shape.

8. A semiconductor device comprising:
a wiring board constructed from a substrate, a connection pad provided on one surface of the substrate, a land provided on the other surface of the substrate and electrically connected to the connection pad, and solder resist provided on the other surface of the substrate so as to expose at least a part of the land;
a semiconductor chip electrically connected to the connection pad; and
a sealing element mounted on one surface of the wiring board, the sealing element covering at least one surface of the wiring board and a part or the whole surface of the semiconductor chip,
wherein the wiring board is the wiring board of the semiconductor device as claimed in claim 1.

9. A mother board comprising the wiring board of the semiconductor device as claimed in claim 1.

10. An electronic apparatus comprising a mother board on which the semiconductor device as claimed in claim 8 is mounted or the mother board as claimed in claim 9.

11. A method of manufacturing a wiring board of a semiconductor device, the method comprising:
providing solder resist so as to partially cover a surface of a substrate, a side surface and a vicinity of a periphery of a top surface of a land on the substrate,
wherein the providing solder resist comprises processing the solder resist so as to comprise a contact portion that is in contact with the land and a non-contact portion that is not in contract with the land.

12. The method as claimed in claim 11, wherein the providing solder resist comprises providing a plurality of the non-contact portions of the solder resist that are not in contact with the land so as to comprise three times or more of finite rotation symmetry with respect to the center of the land.

13. The method as claimed in claim 11, wherein the providing solder resist comprises providing a plurality of the non-contact portions of the solder resist that are not in contact with the land radially from the center of the land toward a periphery of the land.

14. A method of manufacturing a wiring board of a semiconductor device, the method comprising:
forming a land by forming a metallic thin film on a substrate and then subjecting the metallic thin film to selective etching; and
forming a plurality of concave portions and/or convex portions provided so as to comprise three times or more of finite rotation symmetry on the land with respect to the center of the land by further subjecting a surface of the metallic thin film to selective etching.

15. The method as claimed in claim 14, wherein the forming a plurality of concave portions and/or convex portions comprises forming a plurality of concave portions and/or convex portions provided on the land radially from the center of the land toward a periphery of the land.

16. A method of manufacturing an electronic apparatus, the method comprising:
manufacturing a semiconductor device by mounting a semiconductor chip on the wiring board of the semiconductor device as claimed in claim 1, electrically connecting the semiconductor chip to the land, and covering at least one surface of the wiring board of the semiconductor device and a part or the whole surface of the semiconductor chip with a sealing element; and
mounting the semiconductor device on a mother board.

17. A method of manufacturing an electronic apparatus, the method comprising:
manufacturing a mother board comprising features of the wiring board of the semiconductor device as claimed in claim 1; and
mounting the semiconductor device and electronic parts on the mother board.
